(19) United States
(12) Patent Application Publication
(10) Pub. No.: US 2023/0122163 A1
(43) Pub. Date: Apr. 20, 2023

(54) ELECTRONIC DEVICE AND METHOD FOR FABRICATING THE SAME

(71) Applicant: InnoLux Corporation, Miao-Li County (TW)

(72) Inventors: Chao-Sen YANG, Miao-Li County (TW); Chueh-Yuan NIEN, Miao-Li County (TW); Chao-Chin SUNG, Miao-Li County (TW); Chien-Tzu CHU, Miao-Li County (TW)

(21) Appl. No.: 17/932,735

(22) Filed: Sep. 16, 2022

(30) Foreign Application Priority Data
Oct. 18, 2021 (CN) 202111210387.X

(51) Int. Cl. H01L 33/00; H01L 33/62

(52) U.S. Cl. CPC H01L 33/005; H01L 33/62; H01L 2933/0066

(57) ABSTRACT

A method for fabricating an electronic device is provided. The method includes the following steps. A substrate is provided. A solder and a flux are formed on the substrate. An electronic component is bonded on the solder. At least a portion of the flux is removed. An electronic device is also provided.

### CROSS REFERENCE TO RELATED APPLICATIONS

This application claims priority of China Patent Application No. 202111210387.X, filed on Oct. 18, 2021, the entirety of which is incorporated by reference herein.

### BACKGROUND

### Technical Field

The present disclosure relates to an electronic device, and in particular it relates to an electronic device with bonding pads and method for fabricating the same.

### Description of the Related Art

At present, electronic components are soldered on a thin-film transistor (TFT) glass substrate through tin. However, after a reliability test (such as thermal shock), cracks may occur in the glass directly under the electronic components, resulting in bright/dark spots or even the electronic components peeling off the substrate. These abnormal phenomena occur due to the difference in the coefficient of thermal expansion (CTE) between the electronic components and the glass, and the tensile stress occurs after the thermal expansion and contraction process of thermal shock. Eventually, the rupture initiation point occurs at the location of the stress maximum in the structure and extends outward.

### SUMMARY

In accordance with one embodiment of the present disclosure, a method for fabricating an electronic device is provided. The fabrication method includes the following steps. A substrate is provided. A solder and a flux are formed on the substrate. An electronic component is bonded on the solder. At least a portion of the flux is removed.

In accordance with one embodiment of the present disclosure, an electronic device is provided. The electronic device includes a substrate, an electronic component and a glue. The electronic component including a plurality of bonding pads is on the substrate. The glue is between the bonding pads.

A detailed description is given in the following embodiments with reference to the accompanying drawings.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIGS. 1A to 1F show cross-sectional views of a method for fabricating an electronic device in accordance with one embodiment of the present disclosure;

FIG. 1G shows a top view of FIG. 1F in accordance with one embodiment of the present disclosure;

FIGS. 2A to 2D show schematic diagrams of removing flux from an electronic device in accordance with one embodiment of the present disclosure.

### DETAILED DESCRIPTION

Various embodiments or examples are provided in the following description to implement different features of the present disclosure. The elements and arrangement described in the following specific examples are merely provided for introducing the present disclosure and serve as examples without limiting the scope of the present disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

In this specification, spatial terms may be used, such as “below”, “lower”, “above”, “higher” and similar terms, for briefly describing the relationship between an element relative to another element in the figures. Besides the directions illustrated in the figures, the devices may be used or operated in different directions. When the device is turned to different directions (such as rotated 45 degrees or other directions), the spatially related adjectives used in it will also be interpreted according to the turned position. In addition, in this specification, expressions such as “first material layer disposed above/on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer. In some embodiments of the present disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Herein, the terms “about”, “around” and “substantially” typically mean a value is in a range of +/−15% of a stated value, typically a range of +/−10% of the stated value, typically a range of +/−5% of the stated value, typically a range of +/−3% of the stated value, typically a range of +/−2% of the stated value, typically a range of +/−1% of the stated value, or typically a range of +/−0.5% of the stated value. The stated value of the present disclosure is an approximate value. Namely, the meaning of “about”, “around” and “substantially” still exists even if there is no specific description of “about”, “around” and “substantially”.

It should be understood that, although the terms “first”, “second”, “third”, etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

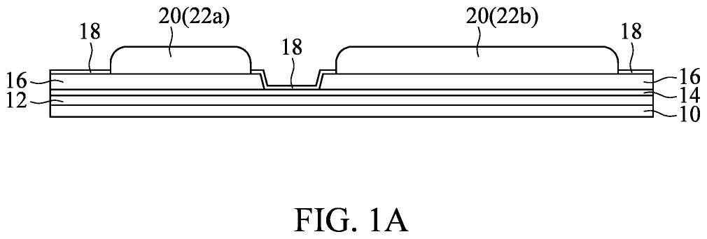

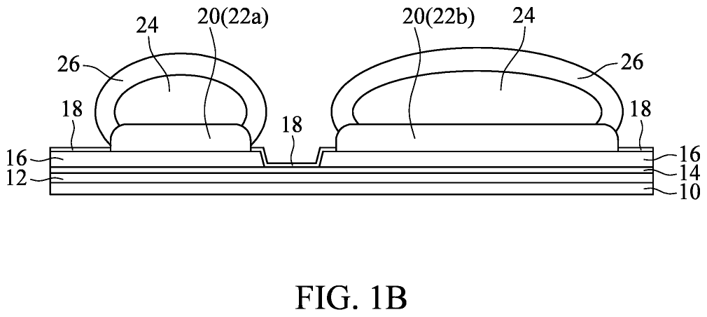

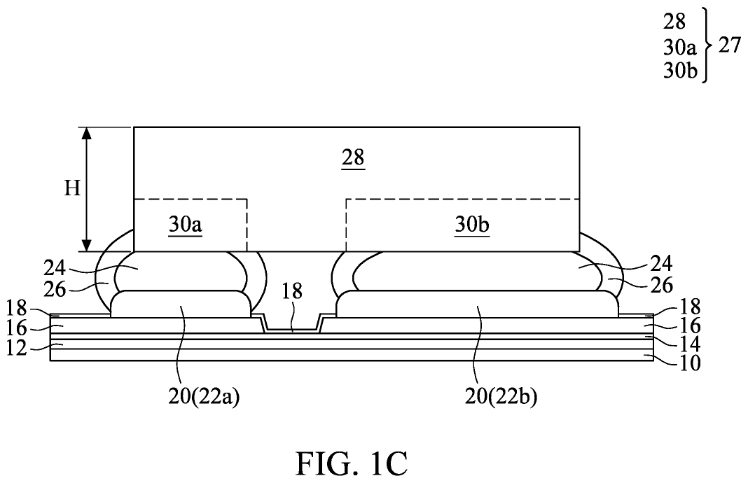

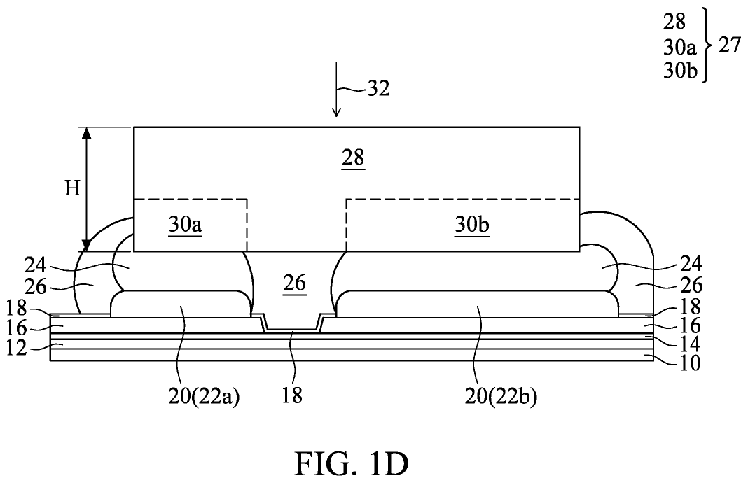

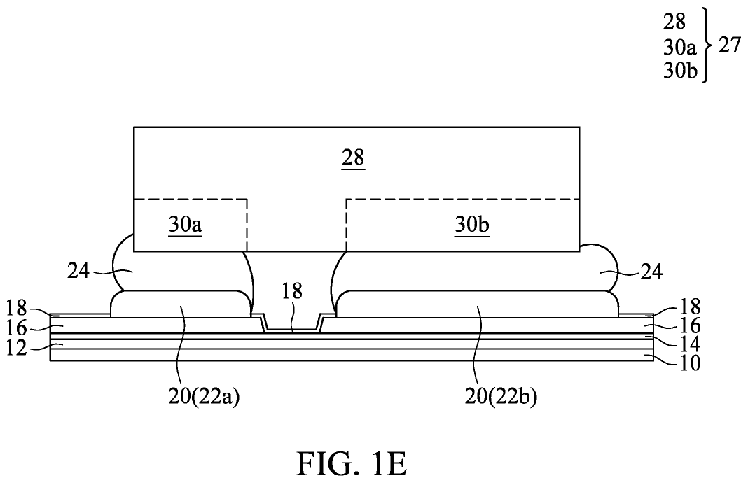

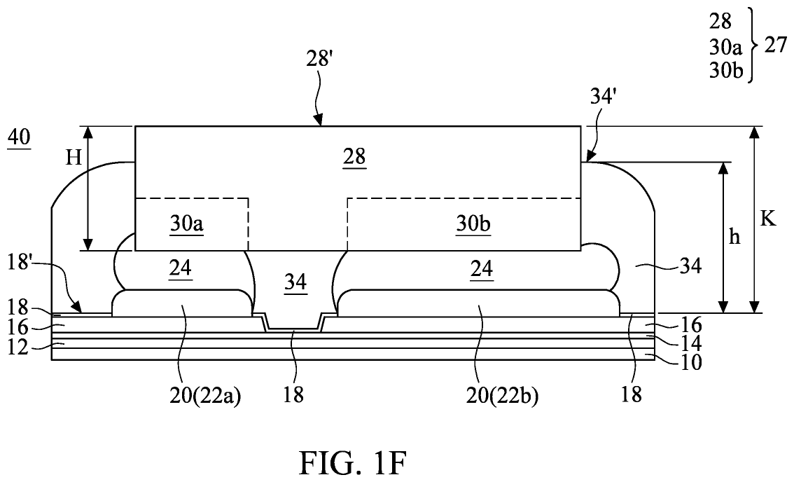

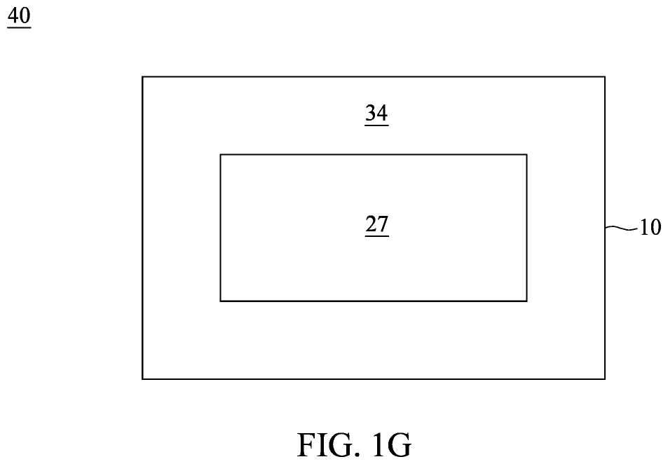

Referring to FIGS. 1A to 1F, in accordance with one embodiment of the present disclosure, a method for fabricating an electronic device is provided. FIGS. 1A to 1F show cross-sectional views of the method for fabricating an electronic device.

As shown in FIG. 1A, a substrate 10 is provided. A first insulating layer 12 is formed on the substrate 10. A second insulating layer 14 is formed on the first insulating layer 12. A patterned metal layer 16 is formed on the second insulating layer 14 to expose a part of the second insulating layer 14. A pixel defining layer (PDL) 18 is formed on the patterned metal layer 16 and the exposed second insulating layer 14, and a part of the patterned metal layer 16 is exposed. A metal layer 20 is formed on the exposed patterned metal layer 16 to define a first bonding structure 22a and a second bonding structure 22b, corresponding to bonding pads of an electronic component to be bonded subsequently.

In some embodiments, the substrate 10 may include a rigid substrate or a flexible substrate, for example, a glass substrate or a polyimide (PI) substrate, but the present disclosure is not limited thereto. In some embodiments, the first insulating layer 12 and the second insulating layer 14 are insulating materials, and may include silicon oxide, silicon nitride or silicon oxynitride, but the present disclosure is not limited thereto. In some embodiments, the patterned metal layer 16 is a metal material, which may include copper, but the present disclosure is not limited thereto. In some embodiments, the pixel defining layer (PDL) 18 is an organic material or an inorganic material, and may include resin, organic silicon, silicon nitride or silicon oxide, but the present disclosure is not limited thereto. In some embodiments, the metal layer 20 is a metal material, which may include nickel, but the present disclosure is not limited thereto.

Next, as shown in FIG. 1B, a solder 24 and a flux 26 are formed on the first bonding structure 22a and the second bonding structure 22b of the substrate 10. In FIG. 1B, first, the solder 24 is formed on the first bonding structure 22a and the second bonding structure 22b, and then, the flux 26 is formed on the solder 24. In some embodiments, the solder 24 and the flux 26 are mixed first to form a mixture, and then, the mixture is formed on the first bonding structure 22a and the second bonding structure 22b. In the present disclosure, the solder 24 and the flux 26 are formed on the first bonding structure 22a and the second bonding structure 22b by, for example, injection coating. In some embodiments, the solder 24 is first formed on the first bonding structure 22a and the second bonding structure 22b by injection coating, and then, the flux 26 is formed on the solder 24 by injection coating again. In some embodiments, first, the solder 24 and the flux 26 are mixed to form a mixture, and then, the mixture is formed on the first bonding structure 22a and the second bonding structure 22b by injection coating. In some embodiments, the solder 24 is a metal or alloy material, and may include tin or tin-bismuth alloy, but the present disclosure is not limited thereto. In some embodiments, the flux 26 is a mixture of resin and organic solvent, which may include rosin, organic acid, alcohol, thickener or other ingredients, but the present disclosure is not limited thereto.

Next, as shown in FIG. 1C, an electronic component 27 is bonded to the solder 24 and the flux 26, wherein the electronic component 27 includes a first bonding pad 30a, a second bonding pad 30b and a main body 28. In FIG. 1C, the electronic component 27 is bonded to the solder 24 and the flux 26 by the first bonding pad 30a and the second bonding pad 30b. In some embodiments, the electronic component 27 may include passive or active components such as capacitors, resistors, inductors, diodes, transistors, etc. The diodes may include light-emitting diodes or photodiodes, such as organic light-emitting diodes (OLEDs), sub-millimeter light-emitting diodes (mini LEDs), micro light-emitting diodes (micro LEDs) or quantum dot LEDs, but the present disclosure is not limited thereto. In some embodiments, the thickness H of the electronic component 27 is about 600 micrometers. In some embodiments, the first bonding pad 30a and the second bonding pad 30b may include copper, but the present disclosure is not limited thereto.

Next, as shown in FIG. 1D, a reflow process 32 is performed. In some embodiments, the reflow process 32 may include low-temperature reflow (reflow temperature below about 170° C.). After reflow, the flux 26 is distributed around the electronic component 27 and located between the first bonding structure 22a and the second bonding structure 22b.

Next, as shown in FIG. 1E, the flux 26 is removed. The relevant removal methods will be described in detail later.

Next, as shown in FIG. 1F, a glue 34 is formed on the substrate 10 and surrounds the electronic element 27 and is located between the first bonding structure 22a and the second bonding structure 22b, as shown in FIG. 1G. FIG. 1G is a top view of FIG. 1F. In the present disclosure, the glue 34 is formed on the substrate 10 by, for example, injection coating, and surrounds the electronic element 27 and is located between the first bonding structure 22a and the second bonding structure 22b. In some embodiments, the Young's modulus of the glue 34 is between about 1 MPa and about 100 MPa. In some embodiments, the glue 34 may include white glue (e.g., based on silicone), optical glue or waterproof glue, but the present disclosure is not limited thereto. In some embodiments, the thickness h of the glue 34 (from the upper surface 18′ of the pixel defining layer (PDL) 18 to the top 34′ of the glue 34) is between about 50 microns and about 600 microns. Here, the height from the upper surface 18′ of the pixel defining layer (PDL) 18 to the upper surface 28′ of the main body 28 of the electronic component 27 is defined as K. In some embodiments, the height K is between about 600 microns and about 640 microns. It is worth noting that the thickness h of the glue 34 does not exceed the height K. So far, the fabrication of the electronic device 40 is completed.

The following will describe in detail how to remove the flux 26.

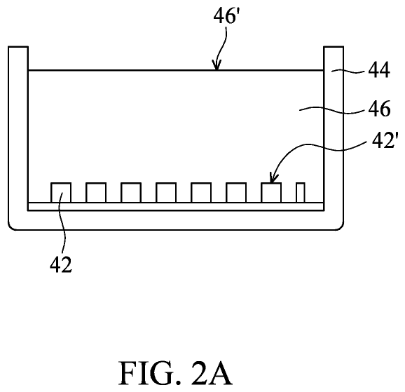

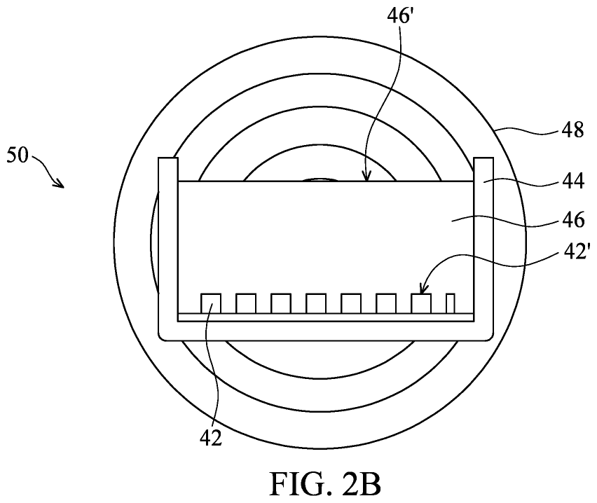

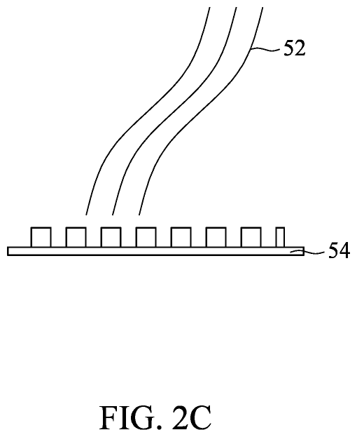

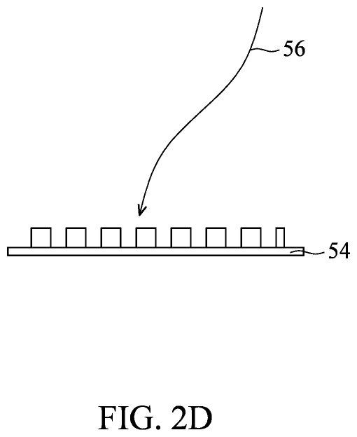

Referring to FIGS. 2A to 2D, in accordance with one embodiment of the present disclosure, a method for removing flux in an electronic device is provided. FIGS. 2A to 2D are schematic diagrams of the above removal method.

As shown in FIG. 2A, the structure 42 (containing the flux) shown in FIG. 1D is placed in a container 44 and detergent 46 is added. In FIG. 2A, the liquid level 46′ of the detergent 46 is higher than the upper surface 42′ of the structure 42 shown in FIG. 1D. In some embodiments, the liquid level 46′ of the detergent 46 is approximately equal to the upper surface 42′ of the structure 42 shown in FIG. 1D. In some embodiments, the liquid level 46′ of the detergent 46 is lower than the upper surface 42′ of the structure 42 shown in FIG. 1D. In the present disclosure, the flux in the structure 42 shown in FIG. 1D is dipped into the detergent 46 to achieve the effect of removing the flux. The upper surface 42′ of the structure 42 shown in FIG. 1D may be lower than, higher than or equal to the liquid level 46′ of the detergent 46. In some embodiments, the detergent 46 may include an alkaline solution, for example, 2-amino-2-methyl-1-propanol, diethylene glycol monobutyl ether, triethylene glycol monobutyl ether, ethylaminoethanol, diethanol, benzyl alcohol, a mixture of two of the aforementioned solutions, or a mixture containing several of the aforementioned solutions, but the present disclosure is not limited thereto. In some embodiments, the temperature of the detergent 46 is between 55° C. and 65° C.

Next, as shown in FIG. 2B, the container 44 containing the structure 42 shown in FIG. 1D and the detergent 46 is placed in an ultrasonic oscillator 48 to perform an ultrasonic shock washing step 50. In some embodiments, the frequency of the ultrasonic shock washing step 50 is about 40 KHz. In some embodiments, the temperature of the ultrasonic shock washing step 50 is about 55° C. to 65° C. In some embodiments, the time of the ultrasonic shock washing step 50 is about 1 minute to 2 minutes. In FIG. 2B, the container 44 containing the structure 42 shown in FIG. 1D and the detergent 46 is placed in the ultrasonic oscillator 48 to perform the ultrasonic shock washing step 50 to remove the flux. In some embodiments, the container 44 containing the structure 42 shown in FIG. 1D alone is placed in the ultrasonic oscillator 48 to perform the ultrasonic shock washing step 50 to remove the flux. In some embodiments, the container 44 containing the structure 42 shown in FIG. 1D and a common solution (e.g., deionized water) is placed in the ultrasonic oscillator 48 to perform the ultrasonic shock washing step 50 to remove the flux.

Next, as shown in FIG. 2C, the structure 54 after the ultrasonic shock washing step 50 is washed with deionized water 52 to remove the detergent 46 without residue, which takes about 1 to 2 minutes.

Next, as shown in FIG. 2D, a drying step 56 is performed on the structure 54 to remove the moisture on the structure 54 and make it dry. At this point, the step of removing the flux is completed, and the structure shown in FIG. 1E is obtained. In some embodiments, the moisture on the structure 54 is removed and blown dry using an air gun, but the present disclosure is not limited thereto. In some embodiments, the moisture on the structure 54 may also be removed and dried by other suitable methods.

Referring to FIG. 1F, in accordance with one embodiment of the present disclosure, an electronic device 40 is provided. FIG. 1F is a cross-sectional view of the electronic device 40.

As shown in FIG. 1F, the electronic device 40 includes a substrate 10, a first insulating layer 12, a second insulating layer 14, a patterned metal layer 16, a pixel defining layer (PDL) 18, a metal layer 20 (including a first bonding structure 22a and a second bonding structure 22b), a solder 24, a first bonding pad 30a, a second bonding pad 30b, a main body 28, and a glue 34. The first insulating layer 12 is formed on the substrate 10. The second insulating layer 14 is formed on the first insulating layer 12. The patterned metal layer 16 is formed on the second insulating layer 14 to expose a part of the second insulating layer 14. The pixel defining layer (PDL) 18 is formed on the patterned metal layer 16 and the exposed second insulating layer 14, and a part of the patterned metal layer 16 is exposed. The metal layer 20 is formed on the exposed patterned metal layer 16 to define the first bonding structure 22a and the second bonding structure 22b, corresponding to bonding pads of an electronic component to be bonded subsequently. The solder 24 is formed on the first bonding structure 22a and the second bonding structure 22b of the substrate 10. An electronic component 27 is bonded to the solder 24 by the first bonding pad 30a and the second bonding pad 30b. The glue 34 is formed on the substrate 10 and surrounds the electronic element 27 and is located between the first bonding structure 22a and the second bonding structure 22b.

In some embodiments, the substrate 10 may include a rigid substrate or a flexible substrate, for example, a glass substrate or a polyimide (PI) substrate, but the present disclosure is not limited thereto. In some embodiments, the first insulating layer 12 and the second insulating layer 14 may include silicon oxide, silicon nitride or silicon oxynitride, but the present disclosure is not limited thereto. In some embodiments, the patterned metal layer 16 may include copper, but the present disclosure is not limited thereto. In some embodiments, the pixel defining layer (PDL) 18 may include resin, organic silicon, silicon nitride or silicon oxide, but the present disclosure is not limited thereto. In some embodiments, the metal layer 20 (including the first bonding structure 22a and the second bonding structure 22b) may include nickel, but the present disclosure is not limited thereto. In some embodiments, the solder 24 may include tin or tin-bismuth alloy, but the present disclosure is not limited thereto.

In some embodiments, the electronic component 27 may include light-emitting diodes (LEDs), such as organic light-emitting diodes (OLEDs), sub-millimeter light-emitting diodes (mini LEDs), micro light-emitting diodes (micro LEDs) or quantum dot LEDs, but the present disclosure is not limited thereto. In some embodiments, the thickness H of the electronic component 27 is about 600 micrometers. In some embodiments, the first bonding pad 30a and the second bonding pad 30b may include copper, but the present disclosure is not limited thereto.

In some embodiments, the Young's modulus of the glue 34 is between about 1 MPa and about 100 MPa. In some embodiments, the glue 34 may include white glue (e.g., based on silicone), optical glue or waterproof glue, but the present disclosure is not limited thereto. In some embodiments, the thickness h of the glue 34 (from the upper surface 18′ of the pixel defining layer (PDL) 18 to the top 34′ of the glue 34) is between about 50 microns and about 600 microns. Here, the height from the upper surface 18′ of the pixel defining layer (PDL) 18 to the upper surface 28′ of the main body 28 of the electronic component 27 is defined as K. In some embodiments, the height K is between about 600 microns and about 640 microns. It is worth noting that the thickness h of the glue 34 does not exceed the height K.

### Example 1

The proportion of cracks in a substrate after thermal shock on an electronic device

The electronic device 40 as shown in FIG. 1F was provided. The materials and dimensions of each component and layer are as follows. The substrate 10 was a glass substrate. The material of the first insulating layer 12 and the second insulating layer 14 was silicon oxide. The material of the patterned metal layer 16 was copper. The material of the pixel defining layer (PDL) 18 was silicon nitride. The material of the metal layer 20 (including the first bonding structure 22a and the second bonding structure 22b) was nickel. The material of the solder 24 was tin. The electronic component 27 was a sub-millimeter light-emitting diode (mini LED) with a thickness H of about 600 microns. The material of the first bonding pad 30a and the second bonding pad 30b was copper. The glue 34 was white glue, and its thickness h is about 100 microns. In the electronic device of this example, after the flux was removed, the glue 34 was formed on the substrate 10 to surround the electronic element 27 and between the first bonding structure 22a and the second bonding structure 22b.

Next, a thermal shock test was performed on the electronic device. The thermal shock test conditions were as follows, with the temperatures ranging from −40° C. to 80° C. for 339 cycles. After the test, the proportion of cracks in the substrate was observed, and the results are shown in Table 1 below.

### Comparative Example 1

The proportion of cracks in a substrate after thermal shock on an electronic device

The electronic device as shown in FIG. 1D was provided. The materials and dimensions of each component and layer are as follows. The substrate 10 was a glass substrate. The material of the first insulating layer 12 and the second insulating layer 14 was silicon oxide. The material of the patterned metal layer 16 was copper. The material of the pixel defining layer (PDL) 18 was silicon nitride. The material of the metal layer 20 (including the first bonding structure 22a and the second bonding structure 22b) was nickel. The material of the solder 24 was tin. The composition of the flux 26 included rosin, organic acid, ethanol, and thickener. The electronic component 27 was a sub-millimeter light-emitting diode (mini LED) with a thickness H of about 600 microns. The material of the first bonding pad 30a and the second bonding pad 30b was copper. In the electronic device of this comparative example, the flux 26 was not removed, and no glue was applied. The flux 26 was formed on the substrate 10 to surround the electronic component 27 and between the first bonding structure 22a and the second bonding structure 22b.

Next, a thermal shock test was performed on the electronic device. The thermal shock test conditions were as follows, with the temperatures ranging from −40° C. to 80° C. for 339 cycles. After the test, the proportion of cracks in the substrate was observed, and the results are shown in Table 1 below.

### Comparative Example 2

The proportion of cracks in a substrate after thermal shock on an electronic device

The electronic device similar to that shown in FIG. 1D was provided. The materials and dimensions of each component and layer are as follows. The substrate 10 was a glass substrate. The material of the first insulating layer 12 and the second insulating layer 14 was silicon oxide. The material of the patterned metal layer 16 was copper. The material of the pixel defining layer (PDL) 18 was silicon nitride. The material of the metal layer 20 (including the first bonding structure 22a and the second bonding structure 22b) was nickel. The material of the solder 24 was tin. The composition of the flux 26 included rosin, organic acid, ethanol, and thickener. The electronic component 27 was a sub-millimeter light-emitting diode (mini LED) with a thickness H of about 600 microns. The material of the first bonding pad 30a and the second bonding pad 30b was copper. The difference between the electronic device of this comparative example and the electronic device of Comparative Example 1 is that the electronic device of this comparative example does not remove the flux 26, but applies part of the glue.

Next, a thermal shock test was performed on the electronic device. The thermal shock test conditions were as follows, with the temperatures ranging from −40° C. to 80° C. for 339 cycles. After the test, the proportion of cracks in the substrate was observed, and the results are shown in Table 1 below.

TABLE 1

| Example/Com. | Comparative | Comparative | |
|---|---|---|---|
| Example | Example 1 | Example 2 | Example 1 |
| | no flux removed, | no flux removed, | flux removed, |
| | no glue applied | part of glue applied | glue applied |
| The proportion | 100% | 93.8% | 0% |
| of cracks (%) | | | |

Here, the “proportion” of cracks in the substrate is defined as the sampling of 100 units, and how many of the 100 units have cracks. From the results in Table 1, it can be seen that when the flux in the electronic device was not removed and the glue was not applied, the proportion of cracks in the substrate was as high as 100% (Comparative Example 1). Although Comparative Example 2 applied part of the glue without removing the flux, the proportion of cracks in the substrate was still quite high, only reduced by about 6%. This reduction in crack proportion is not sufficient to improve product reliability. The reason for the poor improvement effect should be due to the presence of the flux which affects the adhesion of the glue to the substrate. In contrast, in the electronic device of the present disclosure, after the flux is removed, the glue is formed on the substrate and surrounds the electronic component and the first bonding pad and the second bonding pad. After the thermal shock test is performed on this structure, the proportion of cracks in the substrate has been greatly reduced, which is enough to prove that after removing the flux, refilling with glue can effectively improve the reliability of electronic products.

In the present disclosure, after the substrate is soldered, the residual flux is cleaned, and white glue is applied, so that the proportion of cracks in the glass substrate is greatly reduced, and the product reliability is effectively improved. After the glass substrate and the electronic component (for example, light-emitting diode (LED)) are soldered, the flux on the substrate is removed with a cleaning solution. After removing the flux, the glue (e.g., white glue, optical glue, waterproof glue, etc.) is applied on the substrate to absorb stress, and the maximum stress between the electronic component and the thin-film transistor (TFT) glass substrate is reduced. Further, the proportion of cracks in glass is reduced after thermal shock, and the purpose of improving product reliability is finally achieved. The proportion of cracks in the glass under the electronic component of the present disclosure is reduced from 100% to 0%.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. A method for fabricating an electronic device, comprising:
providing a substrate;
forming a solder and a flux on the substrate;
bonding an electronic component on the solder; and
removing at least a portion of the flux.

2. The method for fabricating an electronic device as claimed in claim 1, wherein the step of removing the at least a portion of the flux comprises dipping the substrate bonded with the electronic component in detergent.

3. The method for fabricating an electronic device as claimed in claim 2, wherein the step of removing the at least a portion of the flux further comprises drying the substrate bonded with the electronic device.

4. The method for fabricating an electronic device as claimed in claim 1, wherein the step of removing the at least a portion of the flux comprises cleaning the substrate bonded with the electronic device by ultrasonic means.

5. The method for fabricating an electronic device as claimed in claim 1, further comprising forming a glue on the substrate after the step of removing the at least a portion of the flux.

6. The method for fabricating an electronic device as claimed in claim 5, wherein the electronic component comprises a bonding pad which is bonded to the solder, and the glue surrounds the bonding pad from a top view of the electronic device.

7. The method for fabricating an electronic device as claimed in claim 5, wherein the glue surrounds the electronic component from a top view of the electronic device.

8. The method for fabricating an electronic device as claimed in claim 1, further comprising forming a bonding structure on the substrate, wherein the solder and the flux are formed on the bonding structure.

9. The method for fabricating an electronic device as claimed in claim 8, wherein the solder is formed on the bonding structure, and the flux is formed on the solder.

10. The method for fabricating an electronic device as claimed in claim 8, wherein the solder and the flux are mixed to form a mixture, and the mixture is formed on the bonding structure.

11. The method for fabricating an electronic device as claimed in claim 1, further comprising performing a reflow process before removing the at least a portion of the flux.

12. The method for fabricating an electronic device as claimed in claim 4, wherein the substrate bonded with the electronic device is cleaned by ultrasonic means with detergent.

13. An electronic device, comprising:
a substrate;
an electronic component comprising a plurality of bonding pads on the substrate; and
a glue between the bonding pads.

14. The electronic device as claimed in claim 13, wherein the glue has a thickness ranging from 50 microns to 600 microns.

15. The electronic device as claimed in claim 13, wherein the glue has a Young's modulus ranging from 1 MPa to 100 MPa.

16. The electronic device as claimed in claim 13, wherein the glue comprises white glue, optical glue or waterproof glue.

17. The electronic device as claimed in claim 13, further comprising a metal layer between the substrate and the bonding pads of the electronic component.

18. The electronic device as claimed in claim 17, further comprising a solder on the metal layer, wherein the bonding pads of the electronic component are on the solder.

19. The electronic device as claimed in claim 13, wherein the glue surrounds the bonding pads from a top view of the electronic device.

20. The electronic device as claimed in claim 13, wherein the glue surrounds the electronic component from a top view of the electronic device.
